(19) United States
(12) Patent Application Publication
(10) Pub. No.: US 2002/0134513 A1
(43) Pub. Date: Sep. 26, 2002

(54) Novel thermal transfer apparatus

(76) Inventors: David Palagashvili, Mountain View, CA (US); Alex Schreiber, San Jose, CA (US); Harald Herchen, San Jose, CA (US)

Correspondence Address: Patent Counsel, MS/2061, Legal Affairs Dept., Applied Materials, Inc., P.O. Box 450A, Santa Clara, CA, 95052, US

(21) Appl. No.: 09/815,901

(22) Filed: Mar. 22, 2001

(51) Int. Cl. C23F 1/00; C23C 16/00

(52) U.S. Cl. 156/345.52; 156/345.53; 118/724

(57) ABSTRACT

An apparatus to rapidly transfer thermal energy from a thermal source to a thermal sink, said source and sink being in the form of concentric tubes, and a compressible, multiple turn conductive coil between them.

This invention relates to a novel thermal transfer apparatus to transfer thermal energy from a heat source to a heat sink. More particularly, this invention relates to a thermal transfer apparatus that can transfer thermal energy between a thermal source and a thermal sink that operates independently of the thermal coefficient of expansion of the thermal source and of the thermal sink.

### BACKGROUND OF THE INVENTION

Regulation of temperature using a thermal source and a thermal sink can be done in several known ways. Rapid thermal energy transfer is generally desirable. However, since the materials used for a thermal sink and a thermal source are not generally made of the same materials, or even materials that are thermally matched, i.e., have a like thermal coefficient of expansion (TCE), relative motion between them must be able to be accommodated. They must be loosely put together so they can move with respect to each other as the temperature, and thus the size, of either component changes. If two disparate elements are affixed to each other in a permanent or fixed fashion, then as the temperature between them changes, the difference in their temperature leads to cracking or other damage to the components.

Heretofore thermal transfer means that can move with respect to each other are either fluids, or a soft material, such as putty. For example, a thermal transmitting fluid can be placed between the thermal source and the thermal sink in some type of enclosure. However, the use of thermal fluids is disadvantageous because they are subject to leakage.

Materials such as a thermally conducting putty, e.g., a metal-filled silicone, have also been used to transfer thermal energy between a thermal energy source and a thermal energy sink. The advantage of using a putty rather than a fluid is that the putty does not leak. However, there is only a limited amount of motion that can be accommodated for materials that have a widely differing TCE. Further, since the thermal source and the thermal sink have temperatures that are different during use, the TCE is also different between the putty, the thermal source and the thermal sink. If the layer of putty is too thick, thermal energy transfer is insufficient. If it is too thin, the putty is not able to handle the thermal mismatch. Further, if the thermal coefficient of expansion of the thermal source and the thermal sink is dissimilar, the amount of relative motion that can be accommodated between the two is limited.

Further, fluids and thermal putty must be replaced when the thermal source or thermal sink is replaced; a fluid generally cannot be collected for re-use, and a thermal putty must be scraped away from the thermal source or thermal sink in order to be replaced.

Thus, it would be advantageous to be able to re-use the thermal transfer agent, and highly advantageous in some apparatus to be able to increase the range of relative motion between a thermal source and a thermal sink having widely differing TCE.

### SUMMARY OF THE INVENTION

We have found an improved apparatus for transferring thermal energy from a thermal source to a thermal sink that eliminates the problems of leakage, and one that permits a wide range of motion between the thermal source and the thermal sink. Further, the apparatus functions independently of the thermal coefficient of expansion of these components.

In accordance with the invention, a sandwich is made of a thermal source material and a thermal sink material having between them a thermally conductive spring coil. The spring coil is made of a thermally conductive material so it can transfer thermal energy from the thermal source to the thermal sink, or vice versa, rapidly and effectively.

### BRIEF DESCRIPTION OF THE DRAWING

FIG. 1 illustrates an embodiment of the present apparatus.

FIG. 2 is a cross sectional view of a processing chamber in which the present invention can be used advantageously.

FIG. 3 is an expanded view of a portion of the chamber of FIG. 2.

### DETAILED DESCRIPTION OF THE INVENTION

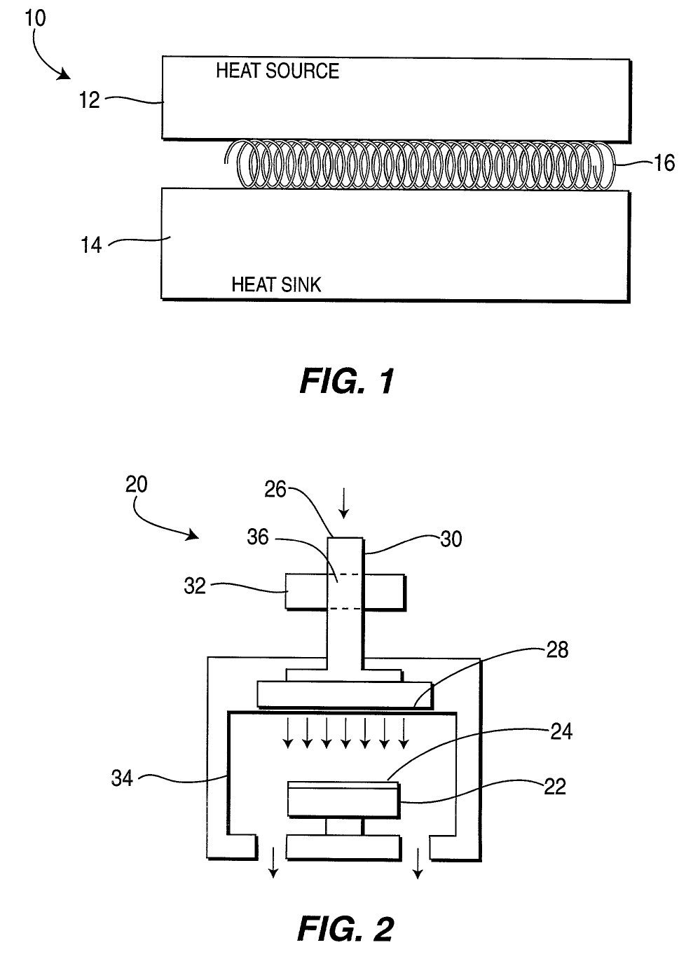

The present apparatus can be illustrated by reference to FIG. 1.

An apparatus 10 of the invention comprises a thermal source 12 and a thermal sink 14 that maintain a thermally conductive spring coil 16 between them. The spring coil 16 is not permanently attached to either the thermal source 12 or the thermal sink 14, and thus the structure is not destroyed or damaged when the source 12 or the sink 14 need to be replaced. The coil spring 16 is compressed between the components as they are stacked together, ensuring many contact points between the coil spring 16 and the thermal source 12 and the thermal sink 14. Thus a rapid thermal transfer capability is maintained while permitting a wide range of motion between the components. This capability can be regulated between the thermal source 12 and the thermal sink 14 and the number of turns of the coil 16. Another advantage of the present apparatus is that the TCE of the thermal source 12 and the thermal sink 14 do not have to match. Because there is no permanent attachment of the coil 16 to either the thermal source 12 or to the thermal sink 14, if either of these components becomes non-functional, they can be readily replaced. Thus the thermal transfer capability is maintained while permitting a wide range of motion between the components. Since there is no permanent connection between the thermal source 12 and the thermal sink 14, the TCE of these parts is irrelevant. This provides a wide choice of the materials for these thermal components.

Suitably the coil spring 16 is made of a highly conductive material, such as copper. The form of the coil, such as a coiled wire, should have intervals as small as possible to obtain many contact points between the thermal source 12 and the thermal sink 14, thereby ensuring a rapid transfer of the thermal energy from one to the other. The wire diameter should be thick enough to conduct heat well, but it must be compressible; if the wire is too thick, the coil will be stiff and cannot be wound into compressible turns. Thus ideally a relatively thin wire of a high conductivity material should be tightly coiled, so as to provide many turns per inch that can provide many contact points between the thermal source 12 and the thermal sink 14. In one embodiment of the present apparatus, the separation of the thermal source and the thermal sink was about 40 mils. The wire was of copper having a wire diameter of 0.011 inch. The number of turns was about 76 loops/linear inch. However, a higher or lower number of turns can be used depending on the spacing between the thermal source and the thermal sink.

The direction of thermal transfer is reversible, simply by transposing the position of the thermal source and the thermal sink. Thus the thermal sink can operate to heat or to cool two parts, such as concentric tubes in a processing chamber.

As an example of the utility of the present invention, reference is made to a semiconductor processing vacuum chamber called an advanced strip and passivation (ASP) chamber. Such a chamber is shown in FIG. 2.

The advanced strip and passivation chamber 20 includes a substrate support 22 which can be temperature controlled. A substrate 24 to be processed is mounted on the support 22. Spaced from and opposed to the support 22 is a gas inlet 26, for passage of one or more processing gases. The gas inlet 26 leads to a sapphire tube 30. This tube 30 passes a source of microwave energy 32. The processing gases are energized as they pass the microwave source 32 to form a plasma. This area is shown as 36 in dotted line. Sapphire is a ceramic-type dielectric that does not absorb microwave energy. However, since sapphire is a dielectric, a rapid increase in its temperature may cause it to crack. The present invention prevents this.

The plasma passes along the sapphire tube 30 through a showerhead-type manifold 28 into a processing chamber 34. The plasma in this case is a source of thermal energy that heats up the sapphire tube 30. Thus in the present embodiment, the sapphire tube 30 is a thermal source.

Although shown as a tube, the sapphire gas inlet 30 can also be made of a plurality of plates that are fitted together in a circular arrangement. This can further reduce the tendency of the sapphire to crack.

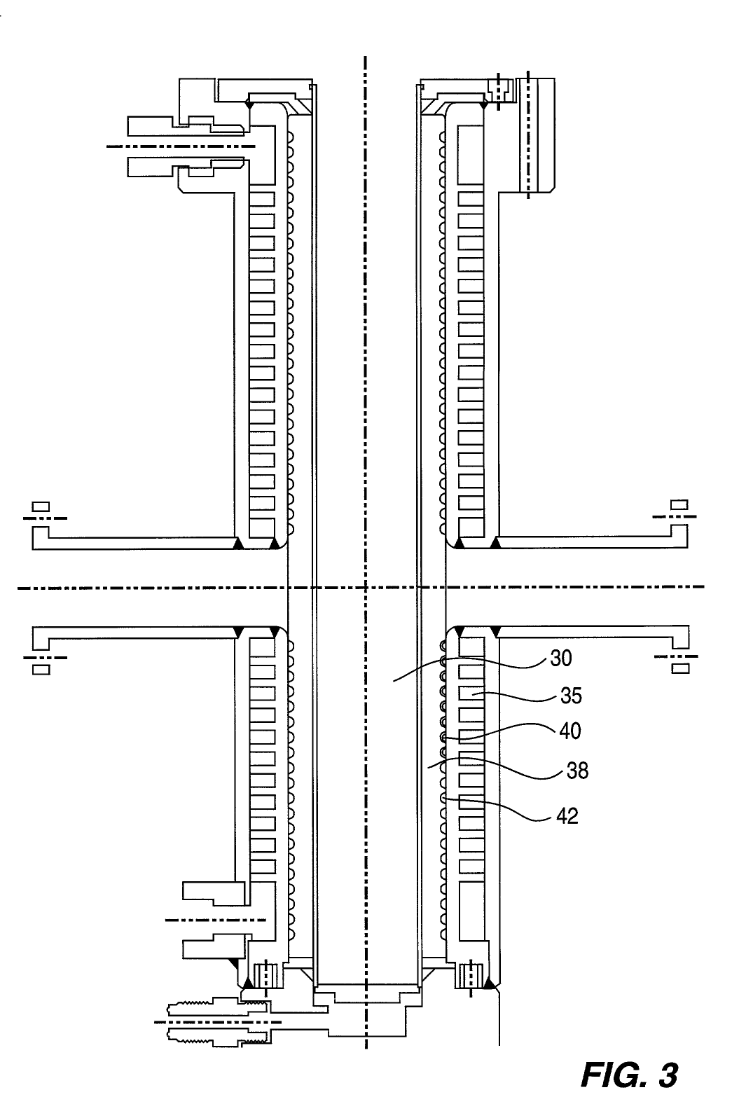

FIG. 3 is an enlarged view of the top portion of the ASP chamber of FIG. 2 showing in greater detail how the present invention may be used. Processing gases pass into the sapphire tube 30. This inlet tube 30 is inserted into a concentric dielectric tubing 38, which can be made of boron nitride or alumina for example, to transfer excess thermal energy from the sapphire tube 30. Suitably the dielectric tube 38 includes cooling means, such as water circulating through a pipe 35. The coolant also must be non-absorbent to microwaves. However, since both the sapphire tube 30 and the dielectric tube 38 are made of ceramics which are both dielectrics, cooling generally is slow.

The present conductive coil 40 of the invention thus can be placed between the sapphire tubing 30 and the ceramic tubing 38 to rapidly transfer thermal energy away from the sapphire tube 30. In the embodiment shown in FIG. 2, the dielectric ceramic tubing 38 has grooves 42 cut into the surface facing the sapphire tube to accommodate the conductive coil 40. Since the conductive and compressible coil 40 expands to fit the space between the sapphire tube 30 and the ceramic tube 38, tight contact between the two tubes is maintained, so that rapid thermal transfer from the inner sapphire tube 30 to the outer ceramic tube 38 is assured.

The apparatus of the invention can be used in any processing chamber that generates plasma or other source of thermal energy that needs to be cooled. This thermal energy in this embodiment is generated by plasma generation, whether using microwave energy, or by lamp or resistance heating.

Although the present invention has been described in terms of specific embodiments of a thermal source and a thermal sink, the invention is not meant to be limited to these details. Other materials, configurations and utility can be substituted, as will be known to those skilled in the art. The invention is only to be limited by the scope of the appended claims.

We claim:

1. A thermal transfer device comprising a thermal source maintained in parallel to a thermal sink and having a thermally conductive, compressible, multiple turn coil between them.

2. A thermal transfer device according to claim 1 wherein the thermal sink surrounds the thermal source.

3. A thermal transfer device according to claim 1 wherein said thermal source is made of a dielectric material.

4. A thermal transfer device according to claim 3 wherein said thermal source is made of sapphire.

5. A thermal transfer device according to claim 1 wherein said thermal sink is made of a dielectric material.

6. A thermal transfer device according to claim 1 wherein said thermally conductive coil is made of copper.

7. A thermal transfer device according to claim 6 wherein said copper coil is made from copper wire about 0.011 inch thick.

8. A thermal transfer device according to claim 1 wherein the thermal source and the thermal sink are concentric.

9. A thermal transfer device according to claim 8 wherein the outer wall of the thermal sink is grooved to accommodate the compressive coil.

10. A thermal transfer device according to claim 2 wherein the thermal sink includes a means of cooling.

11. A thermal transfer device according to claim 1 wherein the conductive, compressible, multiple turn coil fills the gap between the thermal source and the thermal sink.

14. In a vacuum chamber comprising a processing chamber including a substrate to be processed, a processing gas inlet source that traverses a microwave energy source for forming a plasma from the processing gas, the improvement comprising
a microwave impervious gas inlet made of a dielectric material in the form of a tube that provides a thermal source, the dielectric tube surrounded by a concentric dielectric tube that provides a thermal sink, and a compressible, conductive multiple turn coil between them.

13. A vacuum chamber according to claim 12 wherein said coil is made of copper.

14. A vacuum chamber according to claim 12 wherein said gas inlet source is made of sapphire.
